(19) United States
(12) Patent Application Publication
(10) Pub. No.: US 2008/0037601 A1
(43) Pub. Date: Feb. 14, 2008

(54) Avoiding temperature-related faults of a laser by temperature adjustment

(75) Inventor: Carl Christian Juel Nielsen, Charlottenlund (DK)

Correspondence Address: BIRCH STEWART KOLASCH & BIRCH, PO BOX 747, FALLS CHURCH, VA, 22040-0747, US

(73) Assignee: Torsana Laser Technologies A/S, Nivaa (DK)

(21) Appl. No.: 11/822,420

(22) Filed: Jul. 5, 2007

(30) Foreign Application Priority Data
Jul. 7, 2006 (EP) 06116810.0

(51) Int. Cl. H01S 5/024

(52) U.S. Cl. 372/34

(57) ABSTRACT

A method for preserving a mechanical alignment of a semiconductor laser (100) by use of a temperature control system (101). The semiconductor laser includes an optical mount (110) for mounting a semiconductor laser diode (131) and optical components (132,133). A thermal device (140) and a temperature sensor (180) are used for heating or cooling the optical mount and the semiconductor laser. The method includes adjusting the temperature of the semiconductor laser at a rate less than a predetermined temperature rate by use of the thermal device so as to minimise temperature-related faults, wherein the predetermined temperature rate is experimentally determined and is adapted to the semiconductor laser.

### FIELD OF THE INVENTION

The invention relates to avoiding temperature-related faults of a laser, and in particular to avoiding or reducing temperature-related faults by adjusting the temperature of a semiconductor laser device.

### BACKGROUND OF THE INVENTION

Lasers, for example semiconductor lasers, are typically constructed by mounting the optical components on an optical mount for fixing the relative positions between the optical components. Such optical components may comprise a semiconductor laser diode and belonging lenses, mirrors and other optical components. The optical components may be fixed directly to the optical mount or the optical components may be mounted on adapting mounts that are fixed to the optical mount.

Optical mounts and adapting mounts are typically made of metal, and possibly different metals. It is well known that metals are know to be more or less temperature dependent and, therefore, sizes and shapes of the optical mount may change due to changing temperatures. Accordingly, since optical components and adapting mounts are fixed to the optical mount, stresses may be generated in the optical components, the adapting mounts, and the optical mount. The stresses may result in misalignment of the laser since the fixation of the optical components relative to the optical mount may be lost or altered. Thus, temperature variations that cause changes of sizes and shapes of the optical mount may lead to mechanical faults which again lead to optical misalignments and faults of the laser.

In an attempt to avoid temperature-related faults and optical misalignments, beneficial mechanical designs of an optical mount can made in order to minimise such temperature-related misalignments.

However, such beneficial mechanical designs may be expensive and may require special metals and complex mechanical designs. Accordingly, a problem is to obtain an inexpensive and mechanically simple method for minimising temperature-related faults and misalignments of lasers.

Other effects than temperature-related stresses, as well as combinations of other effects, may cause misalignments. Such other effects may comprise temperature-related changes in tension of adjustments screws and screws used for fixing the optical components, temperature-related changes in the properties of adhesives used for fixing optical components, temperature-related changes in properties of lubricants used in adjusting mechanisms.

U.S. Pat. No. 5,848,082 discloses a heatsink and an optical system provided for use in conjunction with a dissipating semiconductor or electronic device, such as a light source, that generate a large amount of heat and is required to be cooled for optimum performance. The light source may be a laser diode or laser array or bar and is generally mounted on the heatsink with other optical components, such as collimating and focusing lenses, isolators or terminal ends of optical fibers, for coupling the output beam of the light source in aligned relation to these optical elements. Because of the higher temperature operation of such light sources, the heat generated causes thermal expansion of mechanically connected structures, such as between the heatsink for supporting the light source and its associated submount and an underlying support, usually a cooler. Because of the differences in thermal expansion rates between these different structures comprised of materials of different coefficients of expansion, the preset or subsequently adjusted alignment of the output beam with these associated optical components will become misaligned due to mechanical warpage and stress deflection of the heatsink. The disclosed heatsink is designed to provide high efficient heat transfer from the heat dissipated from the device while concurrently absorbing mechanical stresses due to differences in the thermal heat transfer coefficients between the heatsink and the underlying support so that component misalignment does not occur.

Thus, U.S. Pat. No. 5,848,082 discloses a special mechanical design for minimising temperature-related misalignments of lasers and, therefore the disclosure of U.S. Pat. No. 5,848,082 does not provide an inexpensive and mechanical simple method for minimising temperature-related faults and misalignments of lasers.

Hence, an improved method for minimising temperature-related faults and misalignments would be advantageous, and in particular a more efficient and/or reliable method for minimising faults and temperature-related misalignments would be advantageous.

### SUMMARY OF THE INVENTION

Accordingly, the invention preferably seeks to mitigate, alleviate or eliminate one or more of the above mentioned disadvantages singly or in any combination. In particular, it may be seen as an object of the present invention to provide a method for minimising temperature-related mechanical stresses and related faults that solves the above mentioned problems of the prior art which does not provide an inexpensive and mechanical simple method for minimising temperature-related faults and misalignments of lasers.

This object and several other objects are obtained in a first aspect of the invention by providing a method for preserving a mechanical alignment of a semiconductor laser comprised by a laser system, said laser system comprising,
the semiconductor laser, and
a temperature control system adapted for controlling the temperature of the semiconductor laser, wherein the semiconductor laser comprises
   an optical mount for mounting at least one semiconductor laser diode and/or one or more optical components,
   a thermal device capable of heating and/or cooling the optical mount,
   at least one temperature sensor for measuring at least one temperature of the semiconductor laser, wherein the method comprises
adjusting the temperature of the semiconductor laser at a rate less than or equal to a predetermined temperature rate by use of the thermal device, said temperature adjusting being capable of minimising temperature-related faults,
continuing adjusting the temperature until the temperature measured by the temperature sensor reaches an operating temperature, and
maintaining the temperature of the semiconductor laser at the operating temperature during operation of the semiconductor laser, wherein
   the predetermined temperature rate is adapted to the semiconductor laser.

The invention is particularly, but not exclusively, advantageous for obtaining an inexpensive and mechanical simple method for minimising temperature-related faults and misalignments of lasers by minimising temperature-related mechanical stresses.

It may be desirable to be able to preserve a mechanical alignment of a semiconductor laser even after repeated cooling and heating of the semiconductor laser. The mechanical alignment may be an initial alignment of optical components and semiconductor laser diodes that was carried out during manufacturing of the semiconductor laser. The mechanical alignment may comprise positioning of an optical component followed by a subsequent fixation of the optical component. Accordingly, it may be desirable to be able to preserve the fixation of the optical component as well as preserving the initial positioning of the optical component. Such desirable objects may be achieved by the method for preserving a mechanical alignment of a semiconductor laser.

Adjusting the temperature of the semiconductor laser at a rate less than a predetermined temperature rate by use of the thermal device may be an advantage, since this may provide a simple and inexpensive method for minimising temperature-related faults of a semiconductor laser.

It may be an advantage that the predetermined temperature rate is adapted to the semiconductor laser, since different semiconductor lasers may require different predetermined temperature rates in order to obtain the desirable minimisation of the temperature-related faults of a semiconductor laser. Accordingly, the predetermined temperature rate may need to be adapted to a particular semiconductor laser.

It may be desirable to be able to increase the lifetime or durability of a semiconductor laser. This objective may be achieved by the method for preserving a mechanical alignment of a semiconductor laser, since this method may minimise the temperature-related faults and, thus, increasing the lifetime or durability of the semiconductor laser.

The predetermined temperature rate may be less than ten degrees Celsius per minute, preferably less than five degrees per minute, or more preferred less than three degrees per minute. Thus, it may be an advantage that cooling or heating the semiconductor laser at a rate less than ten degrees per minute minimises temperature related faults.

In an embodiment the method according to the first aspect of the invention may comprise the steps of adjusting, continuing adjusting and maintaining the temperature of the semiconductor laser by controlling the temperature in a closed loop feedback system. It may be an advantage using a closed loop feedback system, such as P, PI or PID controllers, since the closed loop feedback system may provide a simple and efficient system for controlling the temperature.

It may be an advantage that the semiconductor laser diode may be selected from the group comprising: a tapered laser diode, a single mode laser diode, a broad area laser diode and a self-modulating pulsed laser diode, since various types of semiconductor laser diodes may benefit from the method according to the first aspect of the invention.

The semiconductor laser may be an external cavity laser comprising at least one wavelength selective component. It may be an advantage that the method according to the first aspect of the invention is capable of minimising temperature-related faults of external cavity lasers, since external cavity lasers may be particular prone to generate temperature-related faults in consequence to heating or cooling of the external cavity laser.

The external cavity laser may for instance comprise a broad area diode emitting light into an external cavity comprising a transmissive wavelength selective component and at least one reflective wavelength selective component, wherein the reflective wavelength selective component may be semi-reflective in order to couple out at laser beam.

In particular the semiconductor laser device may be an external cavity laser comprising a tapered semiconductor laser diode being capable of emitting an output beam through a front facet and emitting a secondary beam through a back facet into an external cavity, said external cavity comprising at least one wavelength selective component.

The temperature may measured by a temperature sensor being attached to the optical mount in the vicinity of the thermal device. It may be an advantage to measure the temperature close to the thermal device, since this provides a faster detection of temperature changes which may provide an improved temperature control of the semiconductor laser.

It may be desirable to measure a temperature gradient of the semiconductor laser, since the temperature gradient may provide a more reliable adjusting of the temperature of the semiconductor laser and, thereby, improve the minimising of temperature-related faults. This object may be achieved by measuring first and second temperatures by use of respective first and second temperature sensors, where the first and second temperature sensors are placed on different positions in the optical mount for measuring a temperature gradient.

The optical mount may comprise a mounting plate and a plurality of adapting devices being fixed to the mounting plate where the adapting devices is adapted for holding the optical components and/or the semiconductor laser diode.

In a second aspect the invention relates to a laser system capable of preserving a mechanical alignment of a semiconductor laser comprised by a laser system, said laser system comprising,
the semiconductor laser, and
a temperature control system adapted for controlling the temperature of the semiconductor laser, wherein the semiconductor laser comprises
   an optical mount for mounting at least one semiconductor laser diode and/or one or more optical components,
   a thermal device capable of heating and/or cooling the optical mount,
   at least one temperature sensor for measuring at least one temperature of the semiconductor laser, wherein the temperature control system is capable of
adjusting the temperature of the semiconductor laser at a rate less than or equal to a predetermined temperature rate by use of the thermal device, said temperature adjusting being capable of minimising temperature-related faults,
continuing adjusting the temperature until the temperature measured by the temperature sensor reaches an operating temperature, and
maintaining the temperature of the semiconductor laser at the operating temperature during operation of the semiconductor laser, wherein
   the predetermined temperature rate is adapted to the semiconductor laser.

The first and second aspect of the present invention may each be combined with any of the other aspects. These and other aspects of the invention will be apparent from and elucidated with reference to the embodiments described hereinafter.

### BRIEF DESCRIPTION OF THE DRAWINGS

The present invention will now be explained, by way of example only, with reference to the accompanying Figures, where

FIG. 1 is a principal sketch of a laser system comprising a semiconductor laser and a temperature control system,

FIG. 2 is a principal sketch of a part of the semiconductor laser,

FIG. 3a is an illustration of a method which minimises the temperature-related faults of the semiconductor laser,

FIG. 3b is an illustration of alternative method for controlling a temperature rate a feedback controller,

FIG. 4a is a graph illustrating a method for determining the predetermined temperature rate,

FIG. 4b shows a measurement of the temperature of a semiconductor laser during adjusting the temperature,

FIG. 5 is an illustration of a laser system comprising an external cavity laser and a temperature control system.

### DETAILED DESCRIPTION OF AN EMBODIMENT

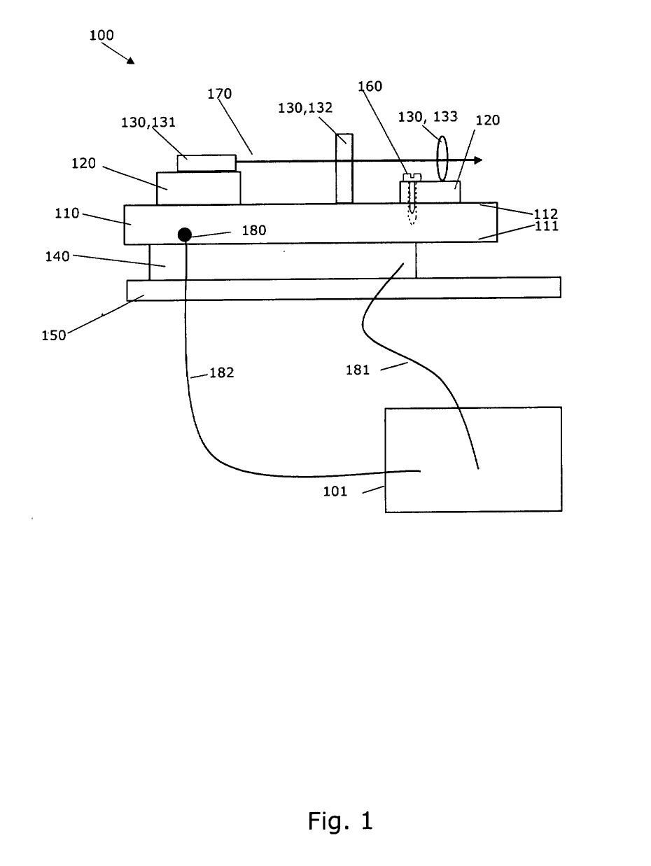

FIG. 1 is a principal sketch of a laser system comprising a semiconductor laser 100 and a temperature control system 101.

The semiconductor laser 100 comprises optical components 130 for instance semiconductor laser diodes, optical filters, gratings, mirrors, wave plates, lenses, frequency doubling crystals and electro-optic components. In FIG. 1, the semiconductor laser device is illustrated as comprising a semiconductor laser diode 131 which generates a beam 132 that is transmitted through an optical filter 132 and beam shaping optics 133. It should be understood that the semiconductor laser device 100 may contain other optical components, and that the semiconductor laser 100 can be of different types, including but not limited to: external cavity lasers, frequency doubled lasers, pumped lasers, pulsed lasers and semiconductor lasers comprising only a laser diode and beam shaping optics. Similarly, the semiconductor laser diode 131 can be of various types, including but not limited to: a single mode laser diode, a broad area laser diode, a tapered laser diode, a DFB diode, a DBR diode and a self-modulating pulsed laser diode. The semiconductor laser 100 also comprises an optical mount 110 for fixing the relative positions and orientations between optical components 130.

The optical components 130 may be mounted directly on the mechanical mount 110 as illustrated with optical components 132. Alternatively, or additionally, the optical components 130 may be mounted on adapting devices 120, as is shown for the semiconductor laser diode 131 and the beam shaping optics 133. The purpose of the adapting devices 120 may be to bring the optical components on line, so that the laser beam 170 for instance impinges centres of the optical components 130. Other purposes of adapting devices 120 are handing devices for enabling handling of small optical components 130 and adjusting devices. For instance the adjusting devices may have adjusting screws for adjusting the position or orientation of optical components 130.

The optical mount 130 and the adapting devices 120 may be made of metals, alloys or other materials, including but not limited to: cobber, brass, bronze, aluminium, beryllium glass, sapphire, ceramics and polymers.

For enabling temperature control of the optical mount 110, adapting devices 120 and optical components 130, a thermal device 140 is thermally connected with the optical mount 110.

The thermal device 140 is capable of heating and/or cooling the optical mount 110, and via heat transfer also the adapting devices 120 and optical components 130 will be heated or cooled.

The thermal device 140 may be an electrically powered heating and/or cooling device, for instance a Peltier element. Alternatively the thermal device may comprise a resistive heating element. The thermal device 140 is electrically powered by a temperature control system 101 via connection 181. A temperature sensor 180 attached to the optical mount 110 provides the temperature control system 181 with a temperature of the optical mount 110 via connection 182.

The temperature sensor 180, can for instance be thermocoupler, an NTC thermistor or a PTC thermistor. The temperature sensor 180 may be surface mounted on the optical mount 110, or the temperature sensor 180 can inserted in a hole made in the optical mount 180. The temperature sensor 180 may be attached to the optical mount 110 in the vicinity of the thermal device 140 close the first boundary 111, or the temperature sensor 180 may be placed elsewhere, for instance close the second boundary 112.

A heat dissipation device 150 capable of conducting heat to, and/or away from, the thermal device 140 may be thermally connected to the thermal device 150. The heat dissipation device can be selected from the list, including but not limited to: a cabinet or closure being part of the semiconductor laser 100, a cooling plate with cooling fins or a liquid cooling device being cooled or heated with a flow of cooling liquid, alternatively being cooled by evaporation or condensation.

By use of some thermal devices 140, for instance resistive heating elements, the heat dissipation device 150 may not be required.

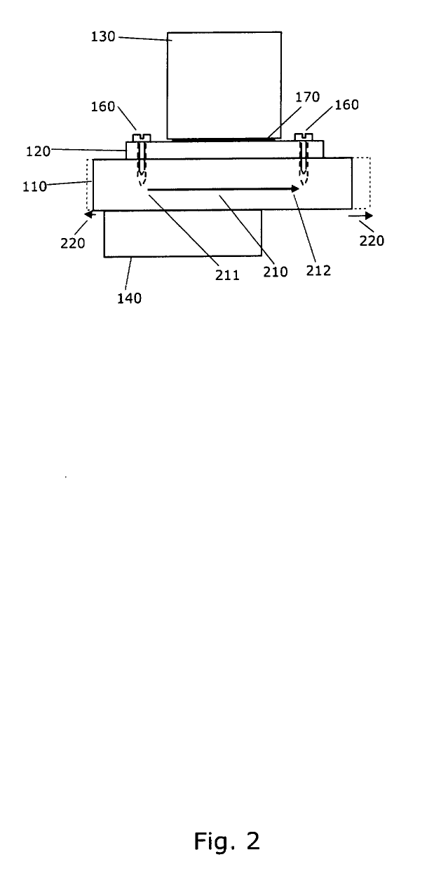

FIG. 2 is a principal sketch of a part of the semiconductor laser 100 showing an optical component 130 fixed to an adapting device 120, for instance by gluing 170, bonding 170, or via mechanical fastening means such as screws. The adapting device 120 is fixed to the optical mount 110 via fastening screws 160. The fastening screws 160 can for instance be capable of performing a micrometer alignment of the position and/or orientation of the optical device 130. The adapting device may also be fixed to the optical mount 110 by other means, for instance by use of adhesive or glue.

In order to obtain stable operation of the semiconductor laser 100, the temperature of the optical components 130, the adapting devices 120 and the optical mount 110 is adjusted until the temperature measured by the temperature sensor 180 reaches an operating temperature. Stable operation of the semiconductor can understood as, but is not limited to, obtaining a stable spectral content of the laser beam 170, obtaining a stable power of the laser beam 170, obtaining stable spatial mode behaviour of the semiconductor laser diode 131, or obtaining mode-hop free behaviour of the semiconductor laser diode 131.

The operating temperature may be predetermined, alternatively, the operating temperature may be determined on basis of laser parameters, for instance laser power, spectral output, or laser stability parameters, for instance during a start-up period of the semiconductor laser.

However, during heating or cooling of the optical mount 110 various effects can generate temperature-related mechanical stresses in the adapting device 120 and the optical component. The mechanical stresses can cause the screws 160 to loosen so that the alignment of the optical component 130 is lost or becomes misaligned. Similarly, the temperature-related mechanical stresses can cause adhesives to crack or to dimensional deform causing misalignment of adapting devices 120 or the optical components 130. The mechanical stresses may even cause the adhesives to crack so that an optical component 130 will fall off. In severe situations the optical component 130 may even be damaged, for instance due to mechanical stresses in glass or crystal.

The temperature-related mechanical stresses may be caused due to various effects. For instance, the material of the optical mount has a limited capability to transfer heat and, therefore, the temperature of the optical mount 110 will become unevenly distributed when the thermal device 140 heats or cools the optical mount 130. The uneven heat distribution, results in a temperature gradient 210 due to for instance a low temperature at the left side 211 and a higher temperature at the right side 212 of the optical mount. The temperature gradient 210 results, for instance, in an expansion 220 of the optical mount 110 which is most pronounced at the higher temperature right side 212 of the optical mount 110 as compared to the lover temperature left side 211. Heat is also transferred to the adapting device 120 so that the adapting device also expands. However, due to the dynamics of heat transfer in the optical mount 110 and the adapting device 120 it is very likely that the optical mount 110 and the adapting device 120 does not expand with similar expansion rates or similar expansion amplitudes. Accordingly, since the adapting device 120 is fixed to the optical mount 110 via screws 160, mechanical stresses will generate deformations in the adapting device 120. Similarly, the mechanical stresses will expose the screws 160 to forces that may cause the screws 160 to loosen so that the alignment of the optical device 130 is lost or altered.

The temperature-related deformations in the adapting device 120 also generates stresses in the optical component 130 and the adhesive 170, which may lead to cracks in the adhesive, changes in the bonding between the adhesive 170 and the optical component 130, dimensional deformations in the adhesive 170 and even damages of the optical component 130.

In cases where the optical component 130 is fixed directly to the optical mount 110, the same temperature-related stresses will cause alignment and damaging problems, as if the optical component 130 was mounted on an adapting device 120.

In general temperature-related alignment and damaging problems caused by heating or cooling of the optical mount 130 are very difficult to analyse and predict. Accordingly, it is difficult to design optical mounts 110 and adapting devices 120 so that these temperature-related mechanical stresses are avoided. For instance the material of the optical mount 110, adapting devices 120 and optical devices may be selected so at to minimise temperature-related mechanical stresses, for instance by using identical metals or by using metals having low thermal expansion coefficients, for instance Invar, Kovar and ceramics. Such attempts to minimise temperature-related mechanical stresses can also be very expensive.

The temperature sensor 180 may be positioned close to the thermal device 140, which may be an advantage since it eliminates the time delay between a change of temperature of the thermal device 140 and the temperature sensor's 180 detection of a corresponding change of temperature. Therefore, positioning the temperature sensor 180 close to the thermal device 140 may provide a faster and more accurate control of the temperature of the optical mount 110.

Alternatively, the temperature sensor 180 may be positioned close to an adapting device 120 or an optical component 130, which may be an advantage since it provides a more accurate temperature measurement of the actual temperature of the optical mount 110, an adapting device 120 or an optical component 130. Therefore, positioning the temperature sensor 180 close to the boundary 112 or close to some adapting device 120 or optical component 130 may provide a more accurate control of the desired temperature of the optical mount 110, the adapting devices 120 or the optical components 130.

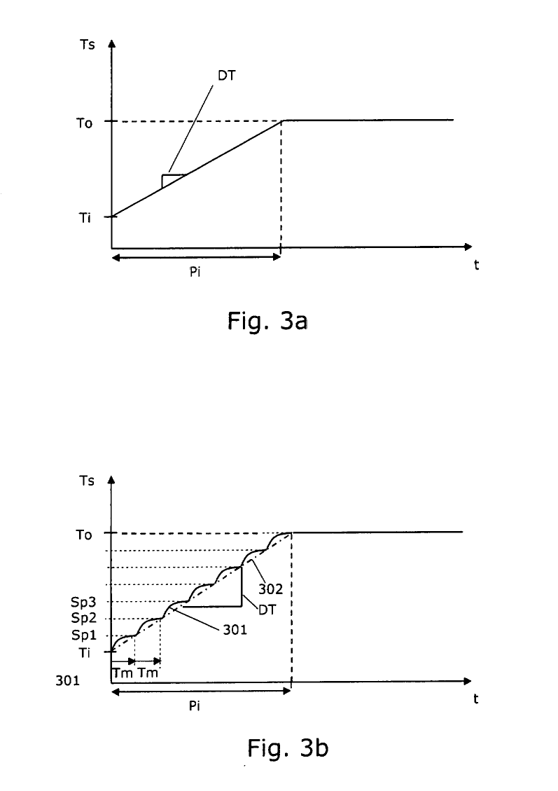

FIG. 3a is an illustration of a method which eliminates, or at least minimises the temperature-related mechanical stresses and the related faults of the semiconductor laser 100 caused by misalignment, lost fixations and damaged optical components. FIG. 3 shows the temperature, Ts, as a function of time, t. The temperature Ts is measured by the temperature sensor 180 and, thus, represents a temperature of the optical mount 110.

During the initial period, Pi, the temperature Ts is increased, alternatively decreased, from an initial temperature Ti at a rate DT less than or equal to a predetermined temperature rate DTp by use of the thermal device 140. The initial temperature Ti may for instance be the temperature of the surroundings. When the temperature Ts reaches the operating temperature To, the temperature of the semiconductor laser 100 is maintained at the operating temperature To during operation of the semiconductor laser.

The operating temperature To may be within the interval from 10-40 degrees Celsius, preferably within 15-35 degrees Celsius, or more preferred with 20-30 degrees Celsius.

The temperature rate DT is controlled by the temperature controller 101. The temperature controller 101 may for instance use a feedback controller, such as a PID controller, to control the temperature rate DT, for instance by applying a ramp reference to the PID controller where the ramp reference has a slope corresponding to the predetermined temperature rate DTp.

Accordingly, the temperature of the semiconductor laser is adjusted at a rate less than a predetermined temperature rate by use of the thermal device during the initial period Pi. The adjusting is continued during the period Pi, until the temperature measured by the temperature sensor 180 reaches the operating temperature To. Subsequent to the initial period Pi, the temperature of the semiconductor laser is maintained at the operating temperature during operation of the semiconductor laser.

FIG. 3b shows an alternative method for controlling the temperature rate DT by the use of the temperature controller 101 being a feedback controller, such as a P, a PI or a PID controller. Initially the temperature controller 101 is supplied with a first set-point Sp1 corresponding to a first constant temperature reference. During a first timer controlled period Tm, the temperature controller 101 increases the temperature 311 until the first timer controlled period Tm has lapsed. When the first timer period Tm has lapsed, a second timer controlled period Tm is started, and a next set-point Sp2 is set. The setting of the next set-point Sp2 is performed by a incremental increase of the set-point relative to the actual temperature Ts measured by the temperature sensor 180 at the time when the first timer period Tm has lapsed. Thus, Sp1 may have been set to 20.1 degrees Celsius, however, when the first timer controlled period Tm has lapsed, the temperature Ts measured by the temperature sensor 180 is only e.g. 20.08 degrees Celsius. If the incremental increase is fixed to 0.1 degrees Celsius, the next set-point Sp2 will be set to 20.08+0.1=20.18 degrees Celsius. When the temperature controller is supplied with the new set-point Sp2, the controller will increase the temperature 311 until the second timer controlled period Tm has lapsed. By supplying the temperature controller 101 with new set-points, until the operating temperature To is reached the temperature 311 being measured by the temperature sensor 180 will increase stepwise. By adapting the timer controlled periods Tm and the set-points to the desired average predetermined temperature rate DTp, it is achieved that the mean temperature rate DT indicated by the average temperature increase 302, remains below or equal to the predetermined temperature rate DTp.

Thus, the methods described in relation to FIGS. 3a and 3b are capable minimising temperature-related faults and, thereby, preserving a mechanical alignment of a semiconductor laser 100.

Minimising temperature-related faults should be understood as minimising the frequency of faults, or as minimising the effect of faults, i.e. the degree of reduction of laser parameters, such as the beam quality or the spectral quality of the emitted laser beam.

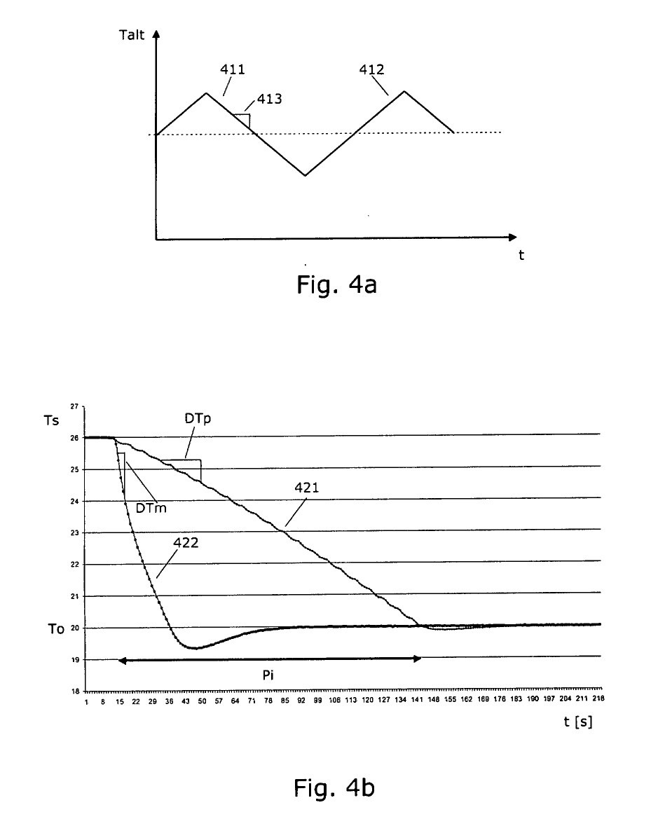

FIG. 4a is a graph illustrating a method for determining the predetermined temperature rate DTp by subjecting the semiconductor laser 100 to an alternating sequence of temperature increases and temperature decreases. The graph in FIG. 4a shows an alternating sequence of increasing 412 and decreasing 411 temperatures Talt. The temperature Talt can be a temperature reference supplied to the temperature controller 101, or the temperature Talt can be a temperature measured by the temperature sensor 180. The alternating sequence of temperature increases 412 and temperature decreases 411 have a slope or temperature rate 413.

Thus, by subjecting the semiconductor laser 100 to a sequence of alternating temperature increases 412, and temperature decreases 411, for instance 500 increases and decreases, having a particular temperature rate 413 the semiconductor laser 100 is subjected to corresponding temperature-related mechanical stresses. During, or subsequent to, subjecting the semiconductor laser 100 to the sequence of alternating temperatures, the laser beam 170 is monitored to determine if the semiconductor laser 100 is subjected to any temperature-related faults.

By gradually increasing or decreasing the temperature rate 413 so as to find the maximum temperature rate 413 where no temperature-related faults affect the semiconductor laser 100, the predetermined temperature rate DTp can be determined as the maximum temperature rate 413 or a temperature rate below the maximum temperature rate 413.

Thus, the predetermined temperature rates DTp are experimentally determined and, therefore, the experiments typically lead to different values of predetermined temperature rates DTp. In particular the predetermined temperature rates DTp depends on which optical components are comprised by the semiconductor laser 100, the materials used for the optical mount 110 and adapting devices 120 and the sizes of the optical mount 110 and the adapting devices. The process described in the above embodies the adaptation of the predetermined temperature rate DTp to the semiconductor laser 100.

It has been experimentally determined that a predetermined temperature rate DTp close to ten degrees Celsius per minute reduces temperature-related faults of the semiconductor laser 100. A predetermined temperature rate DTp less than five degrees per minute results in fewer temperature-related faults. By setting the predetermined temperature rate DTp to less than three degrees per minute a remarkable reduction of temperature-related faults of the semiconductor laser 100 was observed.

FIG. 4b shows measurements of the temperature Ts of a semiconductor laser 100 measured by a temperature sensor 180. The abscissa shows time t measured in seconds s. The ordinate show the temperature Ts measured in degrees Celsius. The first temperature measurement 421 shows the temperature during adjusting, continuing adjusting and maintaining the temperature. The second temperature measurement 422 shows the temperature when the thermal device 140 is allowed to cool the semiconductor laser 100 at the fastest possible temperature rate. That is, the temperature controller 101 is adjusted to provide the fastest temperature change from the initial temperature to the operating temperature.

The initial temperature of the semiconductor laser is approximately 26 degrees Celsius. At t=15 s, the initial period Pi is started, as shown the first temperature curve 421. Thus, at t=15 s, the temperature controller 101 starts adjusting the temperature Ts at a pre-determined temperature rate DTp. The temperature controller continues adjusting the temperature of the semiconductor laser until the operating temperature To has been reached at approximately t=141 s. Subsequent, to the operating temperature To has been reached, the temperature of the semiconductor laser is maintained during a period of time wherein the semiconductor laser is operated. From the temperature curve 421 it is seen that the adapted predetermined temperature rate DTp is approximately equal to 2.9 degrees Celsius per minute.

By utilising the maximum cooling capacity, alternatively heating capacity, of the thermal device 140, the semiconductor laser 100 will be cooled according to the temperature curve 422 which has a maximum temperature rate DTm of approximately 14 degrees Celsius per minute, i.e. a factor of almost five higher the adapted predetermined temperature rate DTp. Accordingly, by exposing the semiconductor laser to rates of temperature changes corresponding to curve 422, the risk of temperature-related faults of the semiconductor laser 100 will be high.

The method for preserving an initial mechanical alignment of a semiconductor laser 100 are applicable to different semiconductor laser devices, for instance external cavity lasers, frequency doubled lasers, pumped lasers and pulsed lasers.

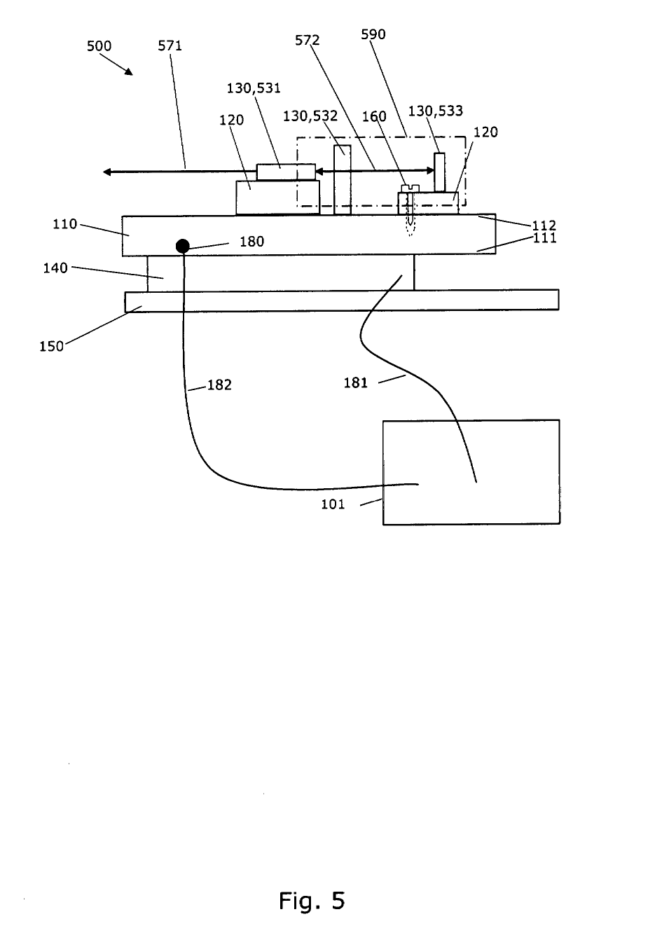

FIG. 5 is an illustration of a laser system comprising an external cavity laser 500 and a temperature control system 101. The temperature control system 101 is equivalent to the temperature control system 101 described in relation to FIG. 1 and, therefore, will not be described further here. Also, any feature in FIG. 5 having the same or similar function as the corresponding feature in FIG. 1 being labelled with the same reference, will not be described in connection with FIG. 5.

The external cavity laser 500 comprises a tapered semiconductor laser diode 531 being capable of emitting an output beam 571 through a front facet and emitting a secondary beam 572 through a back facet into an external cavity 590. The external cavity 590 comprises at least one wavelength selective component. In the example of an external cavity laser in FIG. 5, the external cavity 590 comprises a wavelength selective component 532 which for instance can be a colour-filter or a transmissive grating. The external cavity 590 further comprises a reflective component 533 for coupling the secondary beam 572 back into the laser diode 531. The reflective component 533 can for example be a mirror or a wavelength selective component such as a reflection grating. Similarly, external cavity lasers may comprise broad-area semiconductor laser diodes is combination with an external cavity comprising at least one wavelength selective component, such as a semi-reflective mirror, for out-coupling of the laser beam.

External cavity lasers 500, or other external cavity lasers, comprising for instance broad area laser diodes, require accurate initial alignment of the optical components in the external cavity 590. Accordingly, it is important to avoid temperature-related stresses in the optical mount 110 in order to avoid failures of the optical components, e.g. components 531-533, so as to preserve the initial mechanical alignment.

By using more than one temperature sensor 180, for instance by using a first and a second temperature sensor, it is possible to measure a temperature gradient by determining the difference between a first temperature and a second temperature being measured by the respective first and a second temperature sensor. Since the temperature gradient causes mechanical stresses in the adapting devices 120 and optical components 130, the determination of a temperature gradient may be used to adaptively heating or cooling the optical mount 110 to the operating temperature To. Accordingly, if the measured temperature gradient is below a certain threshold, then the heating or cooling of the optical mount 110 can be continued or the temperature rate DT may even be increased. If the measure temperature gradient is above the threshold, the heating or cooling of the optical mount 110 can be stopped or the temperature rate DT can be lowered so as the decrease the measured temperature gradient. The first and second temperature sensors are positioned with a relative distance, for instance the first temperature sensors can be placed near a left end of the optical mount 110 and the second temperature sensor can be placed near a right end of the optical mount 110. Alternatively, the first temperature sensor may be placed close to the thermal device 140, or close to the first boundary 111, whereas the second temperature sensor may be placed close to the second boundary 112. In another alternative, the first temperature sensor may be placed close to the thermal device 140, or close to the first boundary 111 whereas the second temperature sensor is placed close to a critical adapting device 120 or a critical optical component 130 in order to minimise temperature related stresses of the critical adapting device 120 or the critical optical component 130.

Although the present invention has been described in connection with the specified embodiments, it is not intended to be limited to the specific form set forth herein. Rather, the scope of the present invention is limited only by the accompanying claims. In the claims, the term “comprising” does not exclude the presence of other elements or steps. Additionally, although individual features may be included in different claims, these may possibly be advantageously combined, and the inclusion in different claims does not imply that a combination of features is not feasible and/or advantageous. In addition, singular references do not exclude a plurality. Thus, references to “a”, “an”, “first”, “second” etc. do not preclude a plurality. Furthermore, reference signs in the claims shall not be construed as limiting the scope.

1. A method for preserving a mechanical alignment of a semiconductor laser (100,500) comprised by a laser system, said laser system comprising,
the semiconductor laser (100,500), and
a temperature control system (101) adapted for controlling a temperature (Ts) of the semiconductor laser, wherein the semiconductor laser comprises
an optical mount (110) for mounting at least one semiconductor laser diode (131,531) and/or one or more optical components (130),
a thermal device (140) capable of heating and/or cooling the optical mount (110),
at least one temperature sensor (180) for measuring at least one temperature of the semiconductor laser, wherein the method comprises
adjusting the temperature (Ts) of the semiconductor laser (100,500) at a rate less than or equal to a predetermined temperature rate (DTp) by use of the thermal device (140), said temperature adjusting being capable of minimising temperature-related faults,
continuing adjusting the temperature until the temperature (Ts) measured by the temperature sensor (180) reaches an operating temperature (To), and
maintaining the temperature of the semiconductor laser (100,500) at the operating temperature (To) during operation of the semiconductor laser, wherein
the predetermined temperature rate (Dtp) is adapted to the semiconductor laser.

2. A method according to claim 1, wherein the predetermined temperature rate (Dtp) is less than ten degrees Celsius per minute, preferably less than five degrees per minute, or more preferred less than three degrees per minute.

3. A method according to claim 1, wherein the method comprises, adjusting, continuing adjusting and maintaining the temperature of the semiconductor laser (100,500) by controlling the temperature (Ts) in a closed loop feedback system.

4. A method according to claim 1, wherein the semiconductor laser diode (131) is selected from the group comprising: a tapered laser diode, a single mode laser diode, a broad area laser diode and a self-modulating pulsed laser diode.

5. A method according to claim 1, wherein the semiconductor laser is an external cavity laser (500) comprising at least one wavelength selective component (532).

6. A method according to claim 1, wherein the semiconductor laser is an external cavity laser comprising a tapered semiconductor laser diode (531) being capable of emitting an output beam (571) through a front facet and emitting a secondary beam (572) through a back facet into an external cavity (590), said external cavity comprising at least one wavelength selective component (532,533).

7. A method according to claim 1, wherein the temperature (Ts) is measured by a temperature sensor (180), said temperature sensor being attached to the optical mount (110) in the vicinity of the thermal device (140).

8. A method according to claim 1, wherein first and second temperatures are measured by first and second temperature sensors, said first and second temperature sensors being placed on different positions in the optical mount (110) for measuring a temperature gradient (210).

9. A method according to claim 1, wherein the optical mount (110) comprises a mounting plate and a plurality of adapting devices (120) being fixed to the mounting plate, said adapting devices being adapted for holding the optical components (130) and/or the semiconductor laser diode (131,531).

10. A laser system capable of preserving a mechanical alignment of a semiconductor laser (100,500) comprised by a laser system, said laser system comprising,
the semiconductor laser (100,500), and
a temperature control system (101) adapted for controlling a temperature (Ts) of the semiconductor laser, wherein the semiconductor laser comprises
an optical mount (110) for mounting at least one semiconductor laser diode (131,531) and/or one or more optical components (130),
a thermal device (140) capable of heating and/or cooling the optical mount (110),
at least one temperature sensor (180) for measuring at least one temperature (Ts) of the semiconductor laser, wherein the temperature control system (101) is capable of
adjusting the temperature (Ts) of the semiconductor laser (100,500) at a rate less than or equal to a predetermined temperature rate (DTp) by use of the thermal device (140), said temperature adjusting being capable of minimising temperature-related faults,
continuing adjusting the temperature until the temperature measured by the temperature sensor reaches an operating temperature (To), and
maintaining the temperature of the semiconductor laser at the operating temperature (To) during operation of the semiconductor laser, wherein
the predetermined temperature rate (DTp) is adapted to the semiconductor laser.
